(19) United States
(12) Patent Application Publication
(10) Pub. No.: US 2026/0225182 A1
(43) Pub. Date: Aug. 6, 2026

(54) LASER PROCESSING APPARATUS AND ELECTRONIC DEVICE MANUFACTURING METHOD

(71) Applicant: Gigaphoton Inc., Tochigi (JP)

(72) Inventor: Masanori TERAMOTO, Tochigi (JP)

(73) Assignee: Gigaphoton Inc., Tochigi (JP)

(21) Appl. No.: 19/438,936

(22) Filed: Jan. 2, 2026

(30) Foreign Application Priority Data
Feb. 3, 2025 (JP) 2025-016302

(51) Int. Cl. B23K 26/064; B23K 26/067; G02B 19/00; G02B 26/08; H10W 70/05

(52) U.S. Cl. CPC B23K 26/0648; B23K 26/067; G02B 19/0014; G02B 26/0875; H10W 70/05

(57) ABSTRACT

A laser processing apparatus performs laser processing by irradiating a workpiece with a laser beam output from a laser apparatus, and includes a mask disposed on an optical path of the laser beam and having an opening, an illumination optical system that focuses the laser beam to illuminate the opening, a projection optical system that forms an image of the opening on a surface of the workpiece, a beam splitter disposed between the illumination optical system and the mask to branch the laser beam, an image sensor disposed on an optical path of the laser beam branched by the beam splitter to generate an image including a focal image of the laser beam on the mask, and a processor that corrects a focal position of the laser beam relative to the opening by controlling the illumination optical system based on the image.

### CROSS-REFERENCE TO RELATED APPLICATIONS

The present application claims the benefit of Japanese Patent Application No. 2025-016302, filed on Feb. 3, 2025, the entire contents of which are hereby incorporated by reference.

### BACKGROUND

### 1. Technical Field

The present disclosure relates to a laser processing apparatus and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248.4 nm and an ArF excimer laser apparatus that outputs a laser beam having a wavelength of about 193.4 nm are used.

In addition, an excimer laser beam has a pulse width of about several tens of ns and, due to its short wavelength, is sometimes used for direct processing of polymer materials and glass materials or the like.

A chemical bond in a polymer material can be cut by an excimer laser beam having photon energy higher than bond energy. Therefore, it is known that non-heating processing of a polymer material is made possible by an excimer laser beam, and a processing shape becomes smooth.

In addition, since glass, ceramics, and the like have a high absorptance to an excimer laser beam, it is known that even a material that is difficult to be processed by a visible and infrared laser beam can be processed by an excimer laser beam.

LIST OF DOCUMENTS

### PATENT DOCUMENTS

Patent Document 1: U.S. Patent Application Publication No. 2024/0173796

### SUMMARY

A laser processing apparatus according to one aspect of the present disclosure performs laser processing by irradiating a workpiece with a laser beam output from a laser apparatus, and includes a mask, an illumination optical system, a projection optical system, a beam splitter, an image sensor, and a processor. The mask is disposed on an optical path of the laser beam and is provided with an opening. The illumination optical system is configured to focus the laser beam to illuminate the opening. The projection optical system is configured to form an image of the opening on a surface of the workpiece. The beam splitter is disposed between the illumination optical system and the mask and is configured to branch the laser beam. The image sensor is disposed on an optical path of the laser beam branched by the beam splitter and is configured to generate an image including a focal image of the laser beam on the mask. The processor is configured to correct a focal position of the laser beam relative to the opening by controlling the illumination optical system based on the image.

An electronic device manufacturing method according to one aspect of the present disclosure includes producing an interposer by laser processing an interposer substrate with a laser processing apparatus, coupling and electrically connecting the interposer and an integrated circuit chip to each other, and coupling and electrically connecting the interposer and a circuit substrate to each other. The laser processing apparatus performs laser processing by irradiating a workpiece with a laser beam output from a laser apparatus, and includes a mask disposed on an optical path of the laser beam and provided with an opening, an illumination optical system configured to focus the laser beam to illuminate the opening, a projection optical system configured to form an image of the opening on a surface of the workpiece, a beam splitter disposed between the illumination optical system and the mask and configured to branch the laser beam, an image sensor disposed on an optical path of the laser beam branched by the beam splitter and configured to generate an image including a focal image of the laser beam on the mask, and a processor configured to correct a focal position of the laser beam relative to the opening by controlling the illumination optical system based on the image.

### BRIEF DESCRIPTION OF THE DRAWINGS

Some embodiments of the present disclosure will be described below merely as examples with reference to the accompanying drawings.

FIG. 1 is a diagram schematically illustrating a configuration of a laser processing system according to a comparative example.

FIG. 2 is a diagram schematically illustrating a configuration of a laser apparatus.

FIG. 3 is a diagram schematically illustrating an image of a laser beam with which a mask is irradiated.

FIG. 4 is a diagram illustrating a cold state or a low load state.

FIG. 5 is a diagram illustrating how BD fluctuates in a high load state.

FIG. 6 is a diagram illustrating how BP fluctuates in a high load state.

FIG. 7 is a diagram schematically illustrating a configuration of a laser processing system according to a first embodiment.

FIG. 8 is a diagram schematically illustrating an image of a laser beam with which a mask is irradiated in the first embodiment.

FIG. 9 is a diagram illustrating a cold state or a low load state.

FIG. 10 is a diagram illustrating how BD fluctuates in a high load state.

FIG. 11 is a diagram illustrating how BP fluctuates in a high load state.

FIG. 12 is a diagram explaining a process of calculating a change amount of a focal position based on an image.

FIG. 13 is a diagram explaining an irradiation period and a pause period.

FIG. 14 is a flowchart illustrating an overall flow of position control of a converging lens.

FIG. 15 is a flowchart illustrating a flow of first control.

FIG. 16 is a flowchart illustrating a flow of second control.

FIG. 17 is a diagram schematically illustrating an image of a laser beam with which a mask is irradiated in a modification.

FIG. 18 is a diagram explaining a process of calculating a change amount of a focal position based on an image in the modification.

FIG. 19 is a diagram schematically illustrating a configuration of a laser processing system according to a second embodiment.

FIG. 20 is a diagram illustrating a cold state or a low load state.

FIG. 21 is a diagram illustrating how BD fluctuates in a high load state.

FIG. 22 is a diagram illustrating how BP fluctuates in a high load state.

FIG. 23 is a diagram schematically illustrating a configuration of a laser processing system according to a third embodiment.

FIG. 24 is a diagram illustrating a cold state or a low load state.

FIG. 25 is a diagram illustrating how BP fluctuates in a high load state.

FIG. 26 is a diagram illustrating how BP fluctuates in a high load state.

FIG. 27 is a flowchart illustrating a flow of first control in the third embodiment.

FIG. 28 is a flowchart illustrating a flow of second control in the third embodiment.

FIG. 29 is a diagram schematically illustrating a configuration of an electronic device.

FIG. 30 is a flowchart illustrating an electronic device manufacturing method.

### DESCRIPTION OF EMBODIMENTS

<Contents>
1. Terms
2. Comparative Example
   2.1 Configuration
      2.1.1 Laser Processing System
      2.1.2 Laser Apparatus
   2.2 Operation
   2.3 Problem
3. First Embodiment
   3.1 Configuration
   3.2 Operation
   3.3 Effect
   3.4 Modification
4. Second Embodiment
   4.1 Configuration
   4.2 Operation
   4.3 Effect
   4.4 Modification
5. Third Embodiment
   5.1 Configuration
   5.2 Operation
   5.3 Effect
   5.4 Modification
6. Electronic Device Manufacturing Method
7. Configuration of Processor

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Terms

In the present disclosure, a converging lens refers to a lens capable of converging light beams, with optical power having a positive value. A typical example of a converging lens is a convex lens. Optical power is defined as a reciprocal of a focal length of a lens, and the shorter the focal length, the greater the optical power.

In addition, in the present disclosure, a diverging lens refers to a lens capable of diverging light beams, with optical power having a negative value. A typical example of a diverging lens is a concave lens.

Note that converging lenses and diverging lenses include a set lens for which mirrors and a plurality of lenses that perform substantially equivalent actions are integrated, or combinations of mirrors and lenses.

### 2. Comparative Example

### 2.1 Configuration

### 2.1.1 Laser Processing System

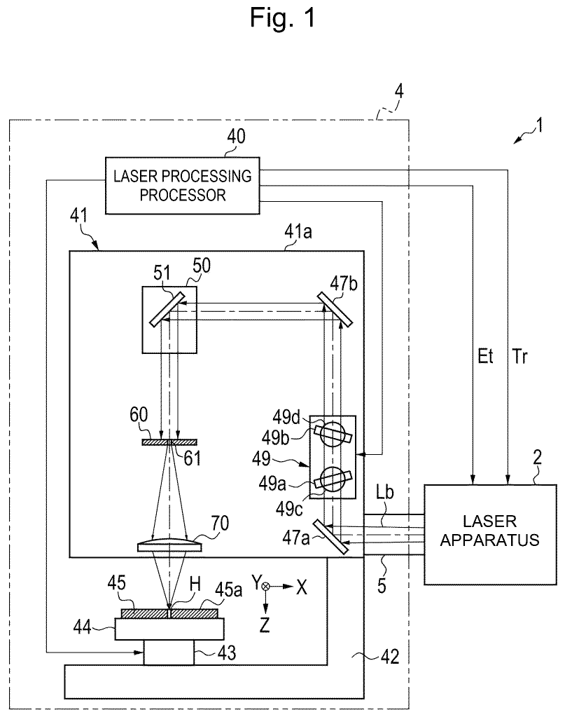

FIG. 1 schematically illustrates a configuration of a laser processing system 1 according to the comparative example. The comparative example is an example recognized by the applicant as known only by the applicant, and is not a publicly known example admitted by the applicant.

The laser processing system 1 mainly includes a laser apparatus 2 and a laser processing apparatus 4. The laser processing system 1 is used for hole processing of forming holes such as via holes in a glass substrate for an interposer.

The laser apparatus 2 outputs an ultraviolet pulse laser beam. For example, the laser apparatus 2 is a discharge excitation type laser apparatus that outputs an ultraviolet pulse laser beam using a laser medium such as F₂, ArF, KrF, XeCl, or XeF. In the present disclosure, the laser apparatus 2 is a KrF excimer laser apparatus that outputs an ultraviolet pulse laser beam having a center wavelength of 248.4 nm. Hereinafter, the ultraviolet pulse laser beam output by the laser apparatus 2 is simply referred to as a laser beam Lb.

The laser apparatus 2 and the laser processing apparatus 4 are connected by an optical path pipe 5. The optical path pipe 5 is disposed so as to surround an optical path of the laser beam Lb between an exit port of the laser apparatus 2 and an entrance port of the laser processing apparatus 4.

The laser processing apparatus 4 includes a laser processing processor 40, an optical system 41, a frame 42, an XYZ stage 43, and a table 44. To the frame 42, the optical system 41 and the XYZ stage 43 are fixed.

A workpiece 45 is an object to be processed, where the hole processing is performed. The workpiece 45 is a glass substrate for an interposer, and is, for example, a non-alkali glass substrate. The workpiece 45 may also be a substrate formed of quartz glass, organic materials, silicon monocrystal, ceramics, metals, or the like. One or more holes H are formed in the workpiece 45.

The XYZ stage 43 supports the table 44. The workpiece 45 is fixed on the table 44. The XYZ stage 43 allows the table 44 to move in X, Y, and Z directions, and changes a position of the workpiece 45 by moving the table 44. The X, Y, and Z directions are orthogonal to each other. The X and Y directions are parallel to a surface 45a of the workpiece 45. The Z direction is orthogonal to the surface 45a. The XYZ stage 43 is connected to the laser processing processor 40.

The optical system 41 includes a housing 41a, high reflective mirrors 47a and 47b, an attenuator 49, an illumination optical system 50, a mask 60, and a projection optical system 70.

Each component in the optical system 41 is fixed to a non-illustrated holder and is disposed at a predetermined position in the housing 41a.

The high reflective mirror 47a reflects the laser beam Lb that has passed through the optical path pipe 5, and is disposed so that the reflected laser beam Lb passes through the attenuator 49 and is incident on the high reflective mirror 47b. The optical path pipe 5 and the housing 41a are, for example, purged with a purge gas. The purge gas is an inert gas such as an N₂ gas, which hardly absorbs the laser beam Lb.

The attenuator 49 is disposed on an optical path between the high reflective mirror 47a and the high reflective mirror 47b in the housing 41a. The attenuator 49 includes, for example, two partial reflective mirrors 49a and 49b and rotating stages 49c and 49d of the partial reflective mirrors. The partial reflective mirrors 49a and 49b are optical elements a transmittance of which changes according to an incident angle of the laser beam Lb. For the partial reflective mirrors 49a and 49b, the incident angle of the laser beam Lb is adjusted by the rotating stages 49c and 49d.

The high reflective mirror 47b reflects the laser beam Lb that has passed through the attenuator 49, and is disposed so that the reflected laser beam Lb enters the illumination optical system 50.

The illumination optical system 50 includes a high reflective mirror 51, and is disposed so as to uniformize a light intensity distribution of the laser beam Lb reflected by the high reflective mirror 47b and to subject the mask 60 to Kohler illumination.

The mask 60 is disposed on an optical path between the illumination optical system 50 and the projection optical system 70. The mask 60 is, for example, a light shielding plate having a light shielding property for shielding the laser beam Lb, and an opening 61 having a shape corresponding to a processing shape of the hole His formed. In the present comparative example, the processing shape is circular, and the opening 61 is a circular pinhole.

For example, when processing a via hole in the workpiece 45, the mask 60 has the opening 61 formed for processing the hole H with a diameter of 5 μm to 30 μm. When a projection magnification of the projection optical system 70 is M, the diameter of the opening 61 may be set to 1/M times the diameter of the hole H to be processed.

Note that the opening 61 is not limited to a hole that physically passes through the mask 60, and includes a transmission part that transmits the laser beam Lb. For the mask 60, a pattern of metal or a dielectric multilayer film may be formed on a synthetic quartz substrate that transmits ultraviolet light, for example. In this case, the opening 61 is formed by the corresponding pattern.

The projection optical system 70 is, for example, an image forming lens, and is disposed so that the laser beam Lb that has transmitted through the opening 61 of the mask 60 forms an image on the surface 45a of the workpiece 45. An image forming surface of the projection optical system 70 is a conjugate plane with a surface of the mask 60 and coincides with the surface 45a of the workpiece 45. That is, the projection optical system 70 forms an image of the opening 61 of the mask 60 on the surface 45a of the workpiece 45. Note that the projection optical system 70 may be a reduction projection optical system.

### 2.1.2 Laser Apparatus

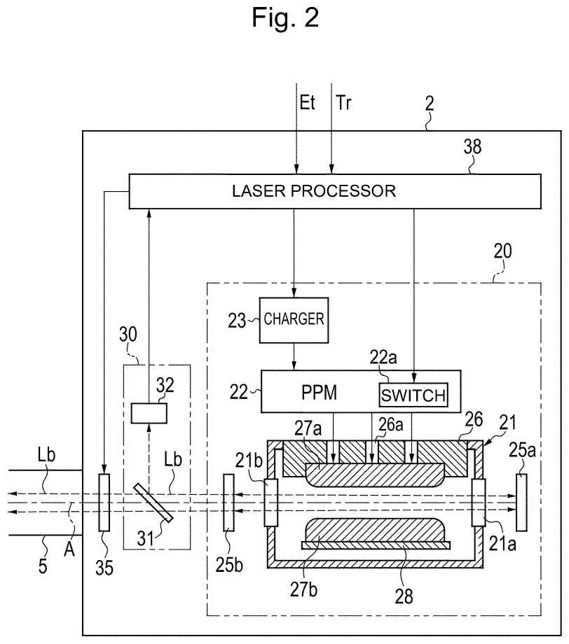

FIG. 2 schematically illustrates a configuration of the laser apparatus 2. The laser apparatus 2 includes an oscillator 20, a monitor module 30, a shutter 35, and a laser processor 38. The oscillator 20 includes a chamber 21, an optical resonator formed of a rear mirror 25a and an output coupling mirror 25b, a charger 23, and a power supply unit (PPM: Pulsed Power Module) 22.

The chamber 21 is provided with windows 21a and 21b. A laser gas as a laser medium is sealed in the chamber 21.

In addition, an opening is formed in the chamber 21, and an electrically insulating plate 26 embedded with a plurality of feedthroughs 26a is provided so as to close this opening. The PPM 22 is disposed on the electrically insulating plate 26. In the chamber 21, a pair of discharge electrodes 27a and 27b as main electrodes and a ground plate 28 are disposed. A discharge surface shape of the discharge electrodes 27a and 27b is rectangular.

The discharge electrodes 27a and 27b are disposed so that their discharge surfaces face each other to excite the laser medium by discharge. The discharge electrode 27a is supported by the electrically insulating plate 26 on a surface on a side opposite to the discharge surface. The discharge electrode 27a is connected to the feedthroughs 26a. The discharge electrode 27b is supported by the ground plate 28 on a surface on a side opposite to the discharge surface.

The PPM 22 includes a switch 22a, and a charging capacitor, a pulse transformer, a magnetic compression circuit, and a peaking capacitor that are not illustrated. The peaking capacitor is connected to the feedthroughs 26a via a non-illustrated connecting portion. The charger 23 charges the charging capacitor based on control from the laser processor 38.

The switch 22a is controlled to be on/off by the laser processor 38. The laser processor 38 turns on the switch 22a in response to a light emission trigger Tr transmitted from the laser processing processor 40.

When the switch 22a is turned on, a current flows from the charging capacitor to a primary side of the pulse transformer, and a reverse current flows to a secondary side of the pulse transformer due to electromagnetic induction. The magnetic compression circuit is connected to the secondary side of the pulse transformer and compresses a pulse width of a current pulse. The peaking capacitor is charged by this current pulse. When a voltage of the peaking capacitor reaches a breakdown voltage of the laser gas, dielectric breakdown occurs in the laser gas between the discharge electrodes 27a and 27b, resulting in discharge. This discharge generates one pulse of the laser beam Lb.

The rear mirror 25a is formed by coating a high reflective film on a planar substrate. The output coupling mirror 25b is formed by coating a partial reflective film on a planar substrate. The chamber 21 is disposed between the rear mirror 25a and the output coupling mirror 25b. The laser beam Lb generated in the chamber 21 is amplified by the optical resonator and is output from the output coupling mirror 25b.

The monitor module 30 includes a beam splitter 31 and a photosensor 32. The beam splitter 31 is disposed on an optical path of the laser beam Lb output from the output coupling mirror 25b, and reflects a portion of the laser beam Lb. The photosensor 32 is disposed at a position where the laser beam Lb reflected by the beam splitter 31 enters. The photosensor 32 measures pulse energy of the laser beam Lb and transmits a measurement value to the laser processor 38.

The laser processor 38 executes control so that the pulse energy of the laser beam Lb output from the laser apparatus 2 becomes target pulse energy Et by changing a charging voltage of the charger 23 based on the measurement value of the pulse energy by the photosensor 32.

The shutter 35 is disposed on an optical path of the laser beam Lb transmitted through the beam splitter 31. The shutter 35 opens and closes in response to commands from the laser processor 38. The laser processor 38 controls output of the laser beam Lb from the laser apparatus 2 by controlling the shutter 35.

### 2.2 Operation

Next, the operation of the laser processing system 1 according to the comparative example will be described. First, the laser processing processor 40 controls the XYZ stage 43 so that the image forming surface of the projection optical system 70 coincides with the surface 45a of the workpiece 45. Next, the laser processing processor 40 transmits the target pulse energy Et to the laser processor 38 and controls a transmittance of the attenuator 49 so that a fluence on the surface 45a becomes a target fluence Ft.

Upon receiving the target pulse energy Et, the laser processor 38 controls the charger 23 so that the pulse energy of the laser beam Lb becomes the target pulse energy Et. Next, the laser processor 38 causes the oscillator 20 to spontaneously oscillate by inputting a trigger to the switch 22a. At this time, the shutter 35 is in a closed state.

A portion of the laser beam Lb output from the chamber 21 via the output coupling mirror 25b is sampled in the monitor module 30 to measure the pulse energy. The laser processor 38 controls the charger 23 so that a difference ΔE between the pulse energy and the target pulse energy Et approaches zero. Then, when the difference ΔE falls within an allowable range, the laser processor 38 transmits a permission signal to the laser processing processor 40 and turns the shutter 35 to an open state.

Upon receiving the permission signal, the laser processing processor 40 transmits the light emission trigger Tr of a predetermined repetition frequency and a predetermined pulse number to the laser apparatus 2. As a result, the laser beam Lb is output from the laser apparatus 2 in synchronization with the light emission trigger Tr and enters the laser processing apparatus 4 through the optical path pipe 5. This laser beam Lb is reflected by the high reflective mirror 47a, is attenuated by the attenuator 49, and is then reflected by the high reflective mirror 47b. The laser beam Lb reflected by the high reflective mirror 47b enters the illumination optical system 50.

The laser beam Lb having entered the illumination optical system 50 is reflected by the high reflective mirror 51 and illuminates a region including the opening 61 of the mask 60. The laser beam Lb transmitted through the opening 61 enters the projection optical system 70.

The projection optical system 70 causes the incident laser beam Lb to form an image on the surface 45a of the workpiece 45. When the surface 45a is irradiated with the laser beam Lb of the predetermined pulse number and the fluence exceeds a processing threshold, laser ablation occurs and the hole His formed.

Next, the laser processing processor 40 controls the XYZ stage 43 and the laser apparatus 2 to repeat change of an irradiation position and irradiation in a step-and-repeat manner, forming the plurality of holes H in an entire processing area where hole processing is required.

### 2.3 Problem

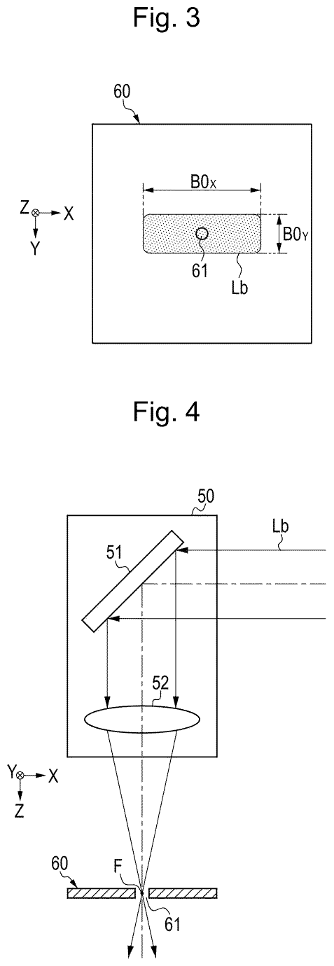

FIG. 3 schematically illustrates an image of the laser beam Lb with which the mask 60 is irradiated. At a position where the mask 60 is disposed, the X direction corresponds to a discharge direction, and the Y direction corresponds to a direction orthogonal to the discharge direction. The laser beam Lb has a characteristic that a beam divergence angle is different in the discharge direction and its orthogonal direction due to the shape and arrangement of the discharge electrodes 27a and 27b. Therefore, the image of the laser beam Lb with which the mask 60 is irradiated has different sizes B0_{X} in the X direction and B0_{Y} in the Y direction.

As illustrated in FIG. 3, the laser beam Lb with which the opening 61 of the mask 60 is irradiated by the illumination optical system 50 has a beam diameter larger than a size of the opening 61, resulting in a low transmittance of the laser beam Lb transmitted through the opening 61. As a result, loss of the pulse energy of the laser beam Lb output from the laser apparatus 2 is significant.

Therefore, as illustrated in FIG. 4, it is conceivable to improve the transmittance by adding a converging lens 52 to the illumination optical system 50 and focusing the laser beam Lb incident from the high reflective mirror 51 to irradiate the opening 61 of the mask 60.

However, if an operating load of the laser apparatus 2 changes, beam divergence (BD) and beam pointing (BP) of the laser beam Lb output from the laser apparatus 2 fluctuate, resulting in change in a focal position F of the laser beam Lb by the converging lens 52. In the present disclosure, the “operating load” refers to the physical influence such as refractive index change and deformation caused in internal optical components by heat generated during the operation of the laser apparatus 2.

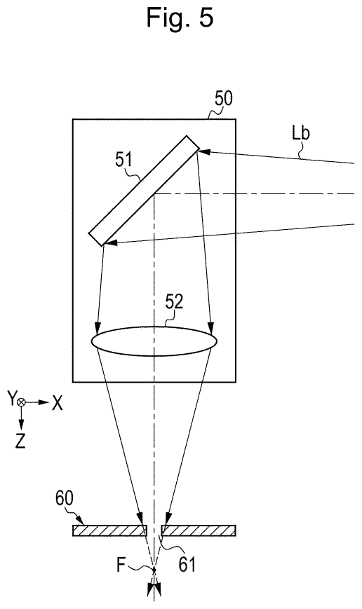

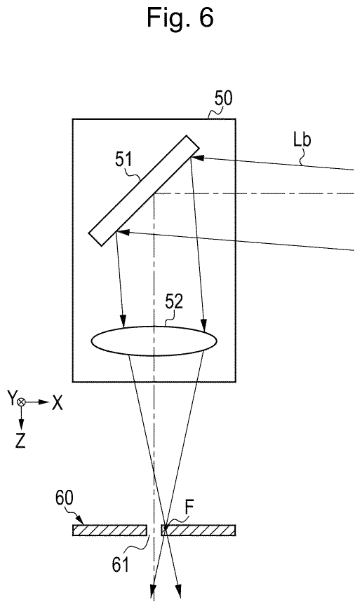

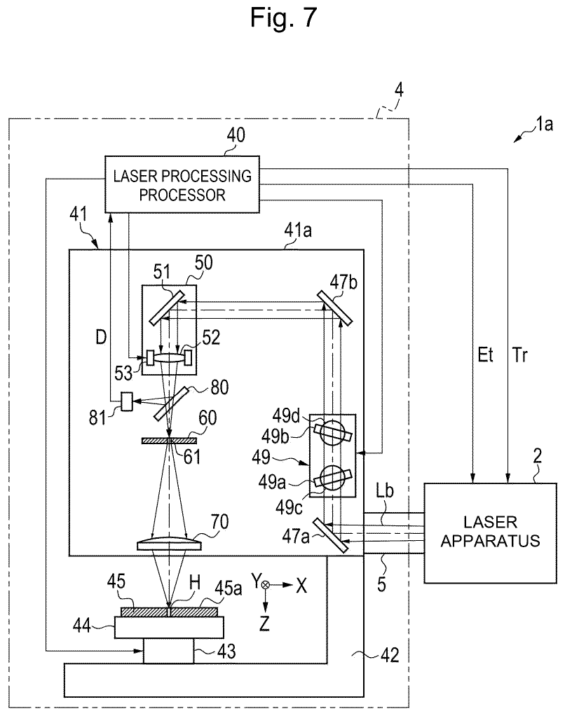

FIG. 4 illustrates a cold state or a low load state. FIG. 5 illustrates how the BD fluctuates in a high load state. FIG. 6 illustrates how the BP fluctuates in the high load state. The operating load of the laser apparatus 2 is lowest in the cold state where pulse oscillation is stopped, and increases as a frequency of the pulse oscillation, elapsed time from a pulse oscillation start, the pulse energy, and the like increase. It is believed that the BD and the BP change due to the influence of the heat generated during the operation of the laser apparatus 2.

The cold state refers to a state where little heat is accumulated inside the laser apparatus 2 before the operation is started and the physical influence of the heat can be ignored. The low load state refers to a state where little heat is accumulated inside the laser apparatus 2 immediately after the operation is started or when the frequency of the pulse oscillation is low and the physical influence of the heat can be ignored.

As illustrated in FIG. 4, in the cold state or the low load state, the BD and the BP are almost stable and the focal position F coincides with a center of the opening 61 of the mask 60, resulting in a high transmittance of the laser beam Lb. As illustrated in FIG. 5, when the BD fluctuates in the high load state, the focal position F changes in the Z direction. In addition, as illustrated in FIG. 6, when the BP fluctuates in the high load state, the focal position F changes in the X or Y direction.

When the focal position F changes in this way, a portion of the laser beam Lb focused by the converging lens 52 is blocked by the mask 60. As a result, the transmittance of the laser beam Lb transmitted through the opening 61 of the mask 60 decreases, and there is a risk that the mask 60 is damaged by the high pulse energy of the laser beam Lb.

While FIG. 4 illustrates an example where the opening 61 of the mask 60 and the focal position F almost coincide with each other in the Z direction, in order to illuminate the opening 61 of the mask 60 with a desired illuminance distribution, such as a uniform illuminance distribution, light may be focused at positions adjacent in the Z direction. Even in such a case, there is a risk of a decrease in transmittance or damage to the mask 60 due to fluctuation of the BD and the BP, and there is a possibility of a problem arising where the conditions for illuminating the opening 61 with a desired illuminance distribution are changed.

The present disclosure provides a laser processing apparatus that enables suppression of a decrease in transmittance and damage to the mask 60 by suppressing fluctuation of the focal position F relative to the opening 61 of the mask 60, and an electronic device manufacturing method.

### 3. First Embodiment

A laser processing system 1a according to the first embodiment of the present disclosure will be described. Configurations similar to those described above are denoted by identical reference signs, and duplicate description thereof is omitted unless otherwise specified.

### 3.1 Configuration

FIG. 7 schematically illustrates a configuration of the laser processing system 1a according to the first embodiment. The laser processing system 1a has the configuration same as that of the laser processing system 1 according to the comparative example, except for the optical system 41.

In the present embodiment, the converging lens 52, a moving stage 53, a beam splitter 80, and an image sensor 81 are added in the optical system 41. The converging lens 52 is disposed so as to focus the laser beam Lb incident from the high reflective mirror 51 and to irradiate the opening 61 of the mask 60. In the present embodiment, the converging lens 52 has optical power in the X and Y directions.

The moving stage 53 holds the converging lens 52 so that it can be moved in the X, Y, and Z directions, respectively. The moving stage 53 is connected to the laser processing processor 40 and is controlled by the laser processing processor 40.

The beam splitter 80 is disposed on an optical path between the illumination optical system 50 and the mask 60 and branches the laser beam Lb incident from the converging lens 52. Specifically, the beam splitter 80 is a partial reflective mirror that reflects a portion of the laser beam Lb that has transmitted through the converging lens 52 and transmits the other portion. In the present embodiment, the laser beam Lb that has transmitted through the beam splitter 80 is incident on the mask 60.

Branching of the laser beam Lb by the beam splitter 80 does not affect projection onto the workpiece 45 via the projection optical system 70, maintaining processing accuracy.

The image sensor 81 is capable of capturing a two-dimensional image, and is disposed such that an imaging surface is orthogonal to an optical axis of the laser beam Lb on an optical path of the laser beam Lb branched by the beam splitter 80. In the present embodiment, the image sensor 81 is disposed on an optical path of the laser beam Lb reflected by the beam splitter 80, and captures a focal image of the laser beam Lb in real time at a position optically conjugate with the mask 60. The image sensor 81 is connected to the laser processing processor 40 and outputs an image D including the focal image to the laser processing processor 40.

In the present embodiment, the laser processing processor 40 corrects the focal position F by measuring a position of the focal image of the laser beam Lb on the mask 60 and the like based on the image D and adjusting a position of the converging lens 52 based on measurement values.

### 3.2 Operation

The operation of the laser processing system 1a according to the first embodiment is the same as the operation of the laser processing system 1 according to the comparative example, except that position adjustment control of the converging lens 52 is additionally performed. Hereinafter, the position adjustment control of the converging lens 52 will be described.

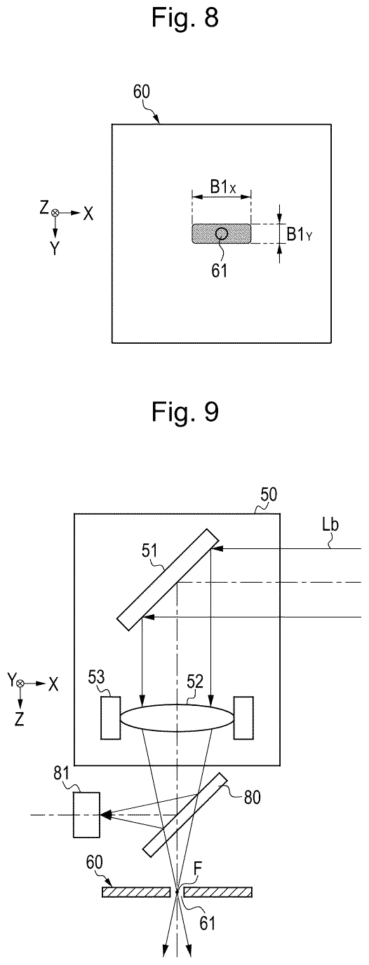

FIG. 8 schematically illustrates the image of the laser beam Lb with which the mask 60 is irradiated in the first embodiment. In the present embodiment, since the converging lens 52 focuses the laser beam Lb in the X and Y directions, the image of the laser beam Lb with which the mask 60 is irradiated is smaller than that in the comparative example. Specifically, a size B1_{X} in the X direction and a size B1_{Y} in the Y direction of the image satisfy relationships of B1_{X}<B0_{X} and B1_{Y}<B0_{Y}.

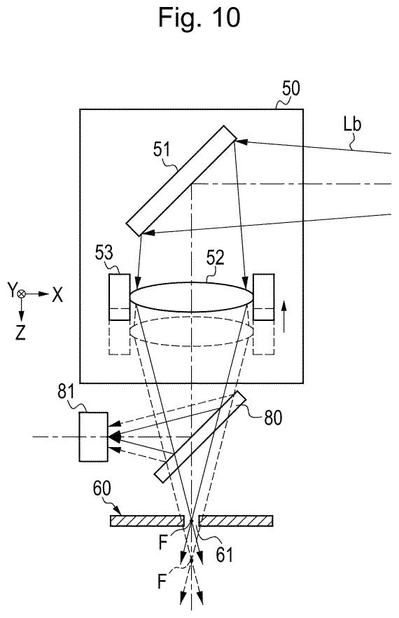

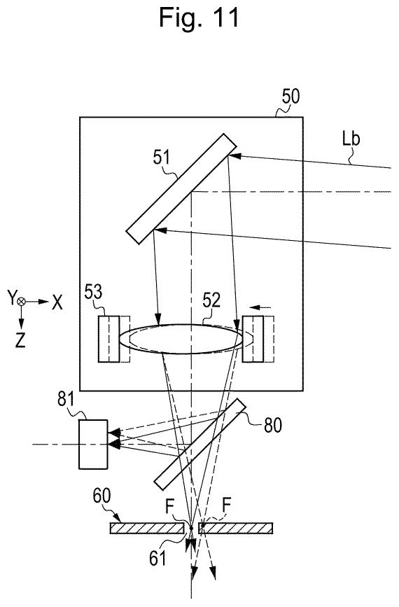

FIG. 9 illustrates the cold state or the low load state. FIG. 10 illustrates how the BD fluctuates in the high load state. FIG. 11 illustrates how the BP fluctuates in the high load state. As illustrated in FIG. 9, in the cold state or the low load state, the focal position F coincides with the center of the opening 61 of the mask 60.

As illustrated in FIG. 10, when the focal position F changes in the Z direction due to the fluctuation of the BD, the laser processing processor 40 controls the moving stage 53 to adjust the position in the Z direction of the converging lens 52. As a result, the focal position Fis corrected to coincide with the center of the opening 61 of the mask 60. FIG. 10 illustrates the converging lens 52, the moving stage 53, and the laser beam Lb before correction with broken lines. The same applies to the figures described below.

As illustrated in FIG. 11, when the focal position F changes in the X or Y direction due to the fluctuation of the BP, the laser processing processor 40 controls the moving stage 53 to adjust the position in the X or Y direction of the converging lens 52. As a result, the focal position F is corrected to coincide with the center of the opening 61 of the mask 60.

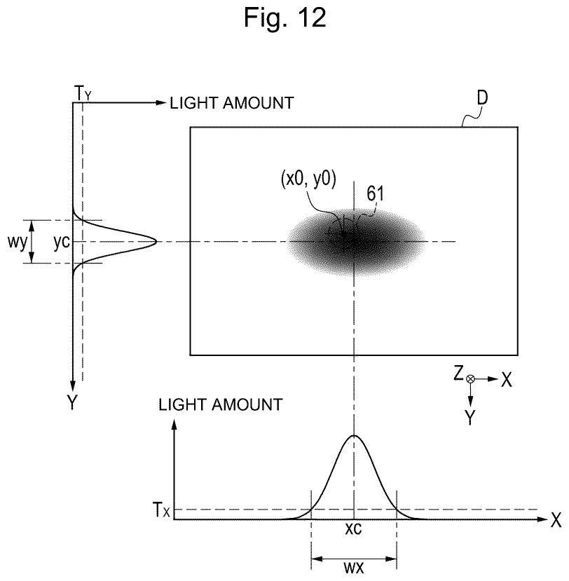

FIG. 12 explains a process of calculating a change amount of the focal position F based on the image D. As illustrated in FIG. 12, in the image D, the focal image of the laser beam Lb is captured. Center coordinates (xc, yc) of the focal image represent positions in the X and Y directions of the focal position F. The center coordinates (xc, yc) are defined as a light amount peak position or a light amount centroid position.

Differences (xdiff, ydiff) between center coordinates (x0, y0) of the opening 61 and the center coordinates (xc, yc) of the focal image correspond to change amounts in the X and Y directions of the focal position F due to the fluctuation of the BP. The differences (xdiff, ydiff) are expressed by following equations (1A) and (1B).

$$[ Expression 1 ]$$

$$xdiff = xc - x 0 \qquad ( 1 A )$$

$$[ Expression 2 ]$$

$$ydiff = yc - y 0 \qquad ( 1 B )$$

The laser processing processor 40 controls the moving stage 53 to move the converging lens 52 in the X and Y directions by correction amounts (Δx, Δy). The correction amounts (Δx, Δy) are expressed by following equations (2A) and (2B).

$$[ Expression 3 ]$$

$$Δ x = C 1 x \times xdiff \qquad ( 2 A )$$

$$[ Expression 4 ]$$

$$Δ y = C 1 y \times ydiff \qquad ( 2 B )$$

Here, C1x and C1y are proportional coefficients in the X and Y directions, respectively, and represent a ratio of a moving amount of the converging lens 52 to a moving amount of the focal position F.

Additionally, a width wx in the X direction and a width wy in the Y direction of the focal image are indirect indicators for identifying the position of the focal position F in the Z direction. While either width wx or wy can be used for identification, in the present embodiment, for example, only the width wx is used for the identification. Specifically, the width in the X direction of the focal image having a light amount larger than or equal to a light amount threshold Tx is measured as the width wx. As the light amount threshold Tx, a full width at half maximum (FWHM) of a light amount distribution of the focal image or the value at which the light amount is 1/e² times a maximum value is generally used.

A difference zdiff between a reference width wx0 and the width wx corresponds to the change amount in the Z direction of the focal position F due to the fluctuation of the BD. The difference zdiff is expressed by a following equation (3). The reference width wx0 is a width in the X direction of the focal image in the cold state.

$$[ Expression 5 ]$$

$$zdiff = w x - wx 0 \qquad ( 3 )$$

The laser processing processor 40 controls the moving stage 53 and moves the converging lens 52 in the Z direction by a correction amount Δz. The correction amount Δz is expressed by a following equation (4).

$$[ Expression 6 ]$$

$$Δ z = C 1 z \times zdiff \qquad ( 4 )$$

Here, C1z is a proportional coefficient in the Z direction, and represents the ratio of the moving amount of the converging lens 52 to the moving amount of the focal position F.

The position control of the converging lens 52 described above is performed during an irradiation period after the laser apparatus 2 has started the operation. The irradiation period refers to a period during which the laser apparatus 2 performs the pulse oscillation and the workpiece 45 is irradiated with the laser beam Lb of the predetermined pulse number. During the irradiation period, every time irradiation with the laser beam Lb is performed, the center coordinates (xc, yc) of the focal image and the width wx of the focal image can be measured based on the image D. Therefore, during the irradiation period, the position of the converging lens 52 can be adjusted in real time based on the measurement values. As a result, during the irradiation period, the focal position F is maintained to coincide with the center of the opening 61 of the mask 60.

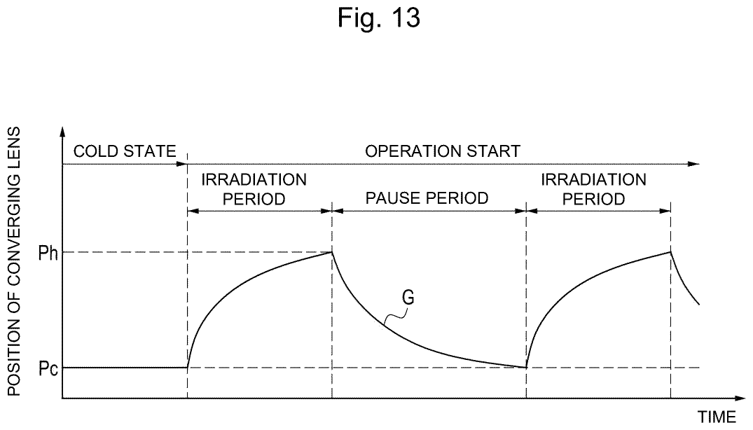

As illustrated in FIG. 13, after the irradiation period ends, another irradiation period starts after a pause period. The pause period is a period during which the laser apparatus 2 stops the pulse oscillation and the workpiece 45 is not irradiated with the laser beam Lb. For example, after a single hole His processed in the workpiece 45, the period during which an irradiation position is changed by the XYZ stage 43 corresponds to the pause period.

During the pause period, since the mask 60 is not irradiated with the laser beam Lb, it is not possible to measure the center coordinates (xc, yc) of the focal image and the width wx of the focal image. Therefore, during the pause period, the laser processing processor 40 corrects the position of the converging lens 52 based on an attenuation curve G expressed by a following equation (5).

$$[ Expression 7 ]$$

$$P = Ph + ( Pc - Ph ) \times ( 1 - {\sum }_{i = 1}^{n} {C}_{i} {e}^{- t / {τ}_{i}} ) \qquad ( 5 )$$

Here, P represents a corrected position of the converging lens 52 during the pause period. Pc is the position of the converging lens 52 in the cold state. Ph is the position of the converging lens 52 at an end of the previous irradiation period. A parameter t is elapsed time from a start of the pause period. A parameter τᵢ is a time constant. A parameter i is a positive integer between 1 and n. Cᵢ is a contribution coefficient of the time constant τᵢ, and satisfies a relationship of a following equation (6).

$$[ Expression 8 ]$$

$${\sum }_{i = 1}^{n} {C}_{i} - 1 \qquad ( 6 )$$

Note that the equation (5) does not distinguish the X, Y, and Z directions. However, in each direction, the position of the converging lens 52 is corrected based on the attenuation curve G expressed by the equation (5). The attenuation curve G represents attenuation of the load due to the heat received during the previous irradiation period.

If the position of the converging lens 52 is not corrected during the pause period, the position at the end of the irradiation period is maintained as is. Therefore, if the focal position F fluctuates due to the attenuation of the load during the pause period, when the irradiation period is resumed, the laser beam Lb immediately after resumption is focused at the focal position F offset from the center of the opening 61 of the mask 60. By correcting the position of the converging lens 52 based on the attenuation curve G during the pause period in this way, the focal position F can be highly accurately maintained at the center of the opening 61.

Hereinafter, the position control of the converging lens 52 during the irradiation period is referred to as “first control,” and the position control of the converging lens 52 during the pause period is referred to as “second control.”

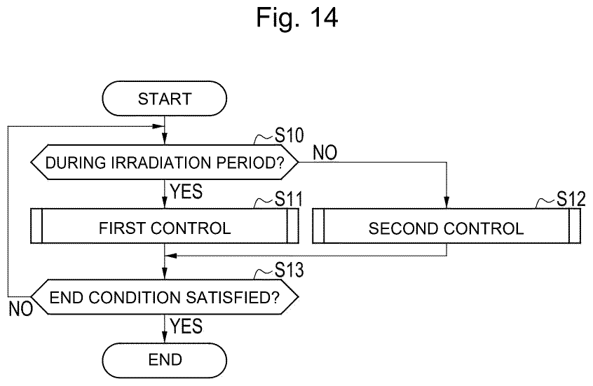

FIG. 14 illustrates an overall flow of the position control of the converging lens 52. First, the laser processing processor 40 determines whether or not a current time point is during the irradiation period after the laser apparatus 2 has started the operation (step S10). If it is during the irradiation period (step S10: YES), the laser processing processor 40 executes the first control (step S11). On the other hand, if it is not during the irradiation period, that is, if it is during the pause period (step S10: NO), the laser processing processor 40 executes the second control (step S12).

After executing the first control or the second control, the laser processing processor 40 determines whether or not an end condition is satisfied (step S13). For example, the end condition is that the laser processing processor 40 has received an end command from an external device. If it is determined that the end condition is not satisfied (step S13: NO), the laser processing processor 40 returns the process to step S10. If it is determined that the end condition is satisfied (step S13: YES), the laser processing processor 40 ends the process.

As a result of the processes, the first control is executed during the irradiation period, and the second control is executed during the pause period.

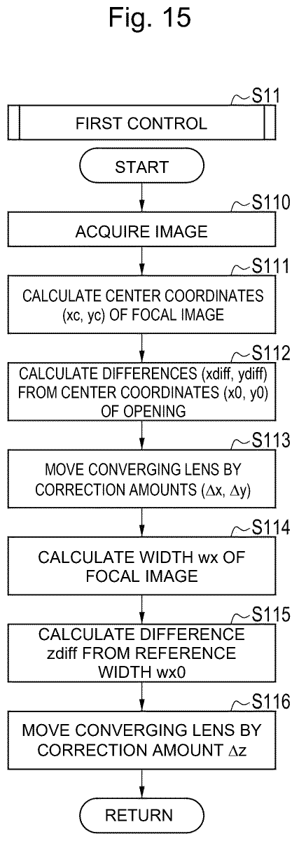

FIG. 15 illustrates a flow of the first control. In the first control, the laser processing processor 40 first acquires the image D output from the image sensor 81 (step S110). Based on the acquired image D, the laser processing processor 40 calculates the center coordinates (xc, yc) of the focal image (step S111). Further, the laser processing processor 40 calculates the differences (xdiff, ydiff) between the calculated center coordinates (xc, yc) and the center coordinates (x0, y0) of the opening 61 (step S112). Next, the laser processing processor 40 controls the moving stage 53 to move the converging lens 52 in the X and Y directions by the correction amounts (Δx, Δy) (step S113).

Subsequently, the laser processing processor 40 calculates the width wx of the focal image based on the image D (step S114). After calculating the difference zdiff between the calculated width wx and the reference width wx0 (step S115), the laser processing processor 40 controls the moving stage 53 to move the converging lens 52 in the Z direction by the correction amount Δz (step S116).

Note that the flow of the first control illustrated in FIG. 15 is just an example, and an order of the processes can be appropriately changed. For example, steps S114 to S116 may be executed before steps S111 to S113. It is also possible to execute steps S111, S112, S114, and S115 first, and then execute steps S113 and S116.

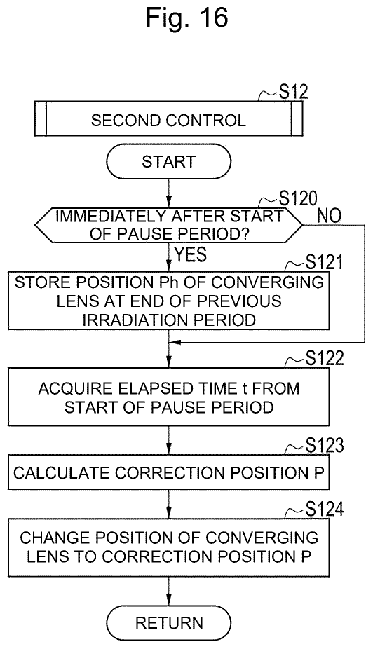

FIG. 16 illustrates a flow of the second control. In the second control, the laser processing processor 40 first determines whether or not the current time point is immediately after the start of the pause period (step S120). If it is determined that it is immediately after the start of the pause period (step S120: YES), the laser processing processor 40 stores a position Ph of the converging lens 52 at the end of the previous irradiation period in a non-illustrated memory (step S121). On the other hand, if it is not immediately after the start of the pause period (step S120: NO), step S121 is not executed.

Thereafter, the laser processing processor 40 acquires elapsed time t from the start of the pause period (step S122) and calculates a correction position P of the converging lens 52 using the equation (5) (step S123). At the time, the laser processing processor 40 uses the position Ph of the converging lens 52 stored in step S121 and the elapsed time t acquired in step S122. Then, the laser processing processor 40 controls the moving stage 53 and changes the position of the converging lens 52 to the correction position P (step S124).

As described above, the laser processing processor 40 changes the focal position F in fixed cycles by executing either the first control or the second control in the fixed cycles.

Here, for example, the fixed cycle is set as an integer multiple of a pulse oscillation cycle of the laser apparatus 2.

### 3.3 Effect

According to the present embodiment, since the laser processing processor 40 corrects the position of the converging lens 52 based on the image D during the irradiation period, it is possible to effectively suppress the fluctuation of the focal position F relative to the opening 61 of the mask 60. As a result, stability of the focal position F is improved and it is possible to prevent a decrease in transmittance and to suppress damage to the mask 60.

Further, since the laser processing processor 40 adjusts the position of the converging lens 52 during the pause period, it is possible to highly accurately maintain the focal position F at the center of the opening 61 of the mask 60 even immediately after the irradiation period is resumed.

### 3.4 Modification

Next, a modification of the first embodiment will be described. In the present modification, the opening 61 of the mask 60 described in the first embodiment is formed in a slit shape and the converging lens 52 is formed as a cylindrical lens further.

In the present modification, the opening 61 of the mask 60 is a slit shape extended in the X direction. In addition, the converging lens 52 is a cylindrical lens that has optical power in the Y direction, which is a width direction of the slit shape, and focuses the laser beam Lb in the Y direction.

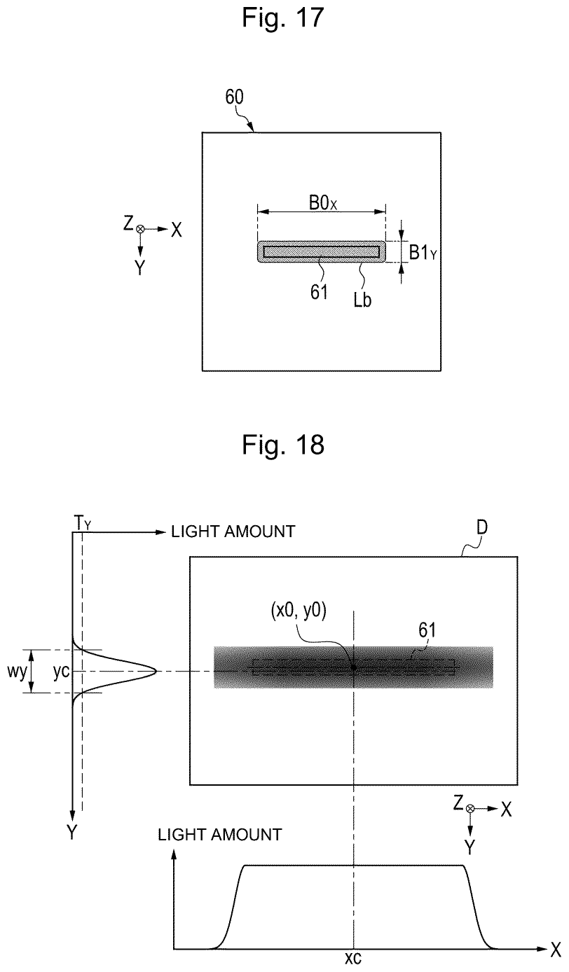

FIG. 17 schematically illustrates the image of the laser beam Lb with which the mask 60 is irradiated in the modification. In the present modification, since the converging lens 52 focuses the laser beam Lb only in the Y direction, the image of the laser beam Lb with which the mask 60 is irradiated becomes longer in the X direction compared to that in the first embodiment. Specifically, since the converging lens 52 does not have optical power in the X direction, the size in the X direction of the image is maintained the same as the size BOX before focusing.

Further, since the converging lens 52 does not have optical power in the X direction, in the present modification, control of the converging lens 52 in the X direction is unnecessary. As a result, an X-direction moving mechanism in the moving stage 53 can be omitted. Specifically, even if the converging lens 52 is moved in the X direction, the focal position F of the laser beam Lb does not fluctuate in the X direction and focusing accuracy relative to the opening 61 of the mask 60 is not affected. Therefore, there is no need to adjust the position of the converging lens 52 in the X direction.

FIG. 18 explains the process of calculating the change amount of the focal position F based on the image D in the modification. As illustrated in FIG. 18, in the image D, the focal image of the laser beam Lb is captured. In the present modification, the laser processing processor 40 only needs to calculate the center coordinate yc in the Y direction and the width wy in the Y direction of the focal image based on the image D. The first control and the second control in the present modification are the same as those in the first embodiment, except that the converging lens 52 is not moved in the X direction.

### 4. Second Embodiment

A laser processing system 1b according to the second embodiment of the present disclosure will be described. Configurations similar to those described above are denoted by identical reference signs, and duplicate description thereof is omitted unless otherwise specified.

### 4.1 Configuration

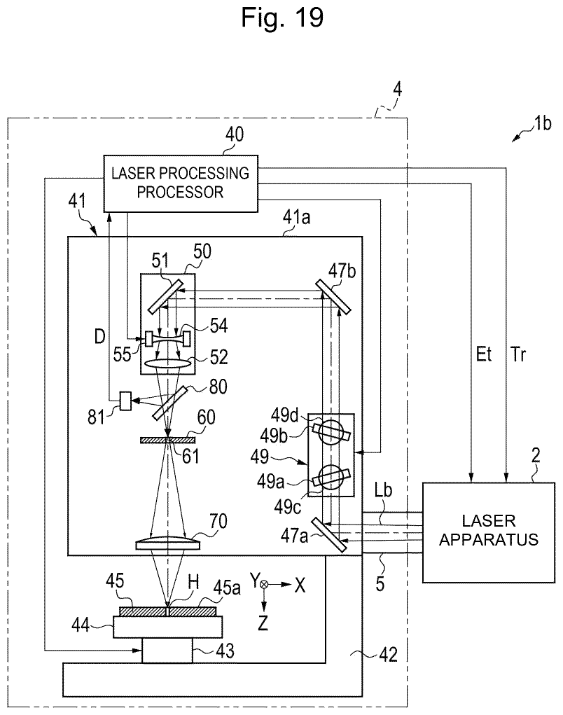

FIG. 19 schematically illustrates a configuration of the laser processing system 1b according to the second embodiment. The laser processing system 1b has the configuration the same as that of the laser processing system 1a according to the first embodiment, except for the illumination optical system 50.

In the present embodiment, the illumination optical system 50 includes the high reflective mirror 51, the converging lens 52, a diverging lens 54 disposed upstream of the converging lens 52, and a moving stage 55 that holds the diverging lens 54. The diverging lens 54 has a role of adjusting a divergence angle of the laser beam Lb and is configured to be movable in the X, Y, and Z directions by the moving stage 55. In the present embodiment, the converging lens 52 is fixed. In addition, in the present embodiment, both the converging lens 52 and the diverging lens 54 have optical power in the X and Y directions, respectively.

The moving stage 55 is connected to the laser processing processor 40 and is controlled by the laser processing processor 40. In the present embodiment, the laser processing processor 40 adjusts the focal position F of the laser beam Lb by moving the diverging lens 54 instead of moving the converging lens 52 as in the first embodiment.

### 4.2 Operation

The operation of the laser processing system 1b according to the second embodiment is the same as the operation of the laser processing system 1a according to the first embodiment, except for position adjustment control of the diverging lens 54. Hereinafter, the position adjustment control of the diverging lens 54 will be described.

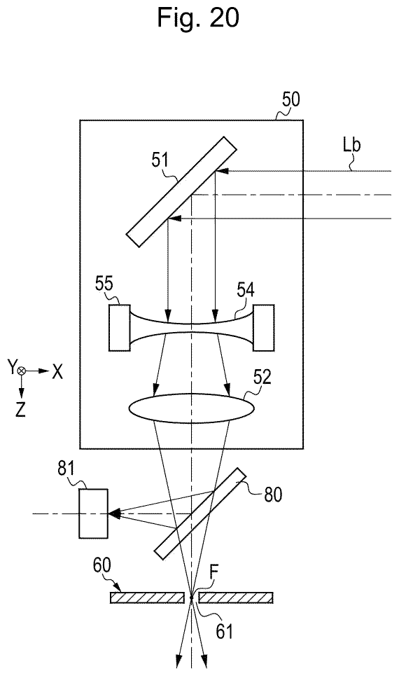

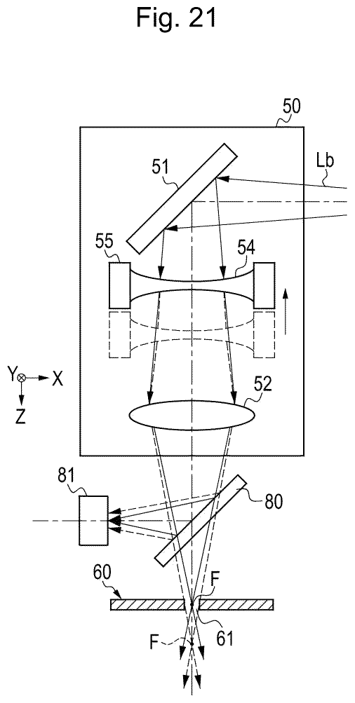

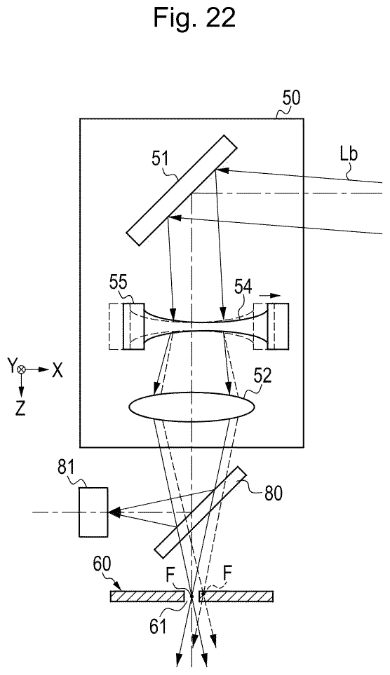

FIG. 20 illustrates the cold state or the low load state. FIG. 21 illustrates how the BD fluctuates in the high load state. FIG. 22 illustrates how the BP fluctuates in the high load state. As illustrated in FIG. 20, in the cold state or the low load state, the focal position F coincides with the center of the opening 61 of the mask 60.

As illustrated in FIG. 21, when the focal position F changes in the Z direction due to the fluctuation of the BD, the laser processing processor 40 controls the moving stage 55 to adjust the position in the Z direction of the diverging lens 54. As a result, the focal position Fis corrected to coincide with the center of the opening 61 of the mask 60.

As illustrated in FIG. 22, when the focal position F changes in the X or Y direction due to the fluctuation of the BP, the laser processing processor 40 controls the moving stage 55 to adjust the position in the X or Y direction of the diverging lens 54. As a result, the focal position F is corrected to coincide with the center of the opening 61 of the mask 60.

The position adjustment control of the diverging lens 54 in the present embodiment is fundamentally the same as the position control of the converging lens 52 in the first embodiment, except that the position of the diverging lens 54 instead of the converging lens 52 is controlled. Specifically, the first control of the present embodiment is executed in a same procedure as the first control in the first embodiment, except that the position of the diverging lens 54 instead of the converging lens 52 is controlled.

In the second control of the present embodiment, when it is immediately after the pause period, control is performed to store the position Ph of the diverging lens 54 at the end of the previous irradiation period, instead of the converging lens 52. In addition, in the second control of the present embodiment, the correction position P of the diverging lens 54 instead of the converging lens 52 is calculated and the position of the diverging lens 54 is changed to the correction position P. The correction position P is calculated based on the attenuation curve G expressed by the equation (5), similarly to the first embodiment. In the present embodiment, Pc is the position of the diverging lens 54 in the cold state.

### 4.3 Effect

According to the present embodiment, since the laser processing processor 40 corrects the position of the diverging lens 54 based on the image D during the irradiation period, it is possible to effectively suppress the fluctuation of the focal position F relative to the opening 61 of the mask 60, similarly to the first embodiment. As a result, the stability of the focal position F is improved and it is possible to prevent a decrease in transmittance and to suppress damage to the mask 60.

Further, since the laser processing processor 40 adjusts the position of the diverging lens 54 during the pause period, it is possible to highly accurately maintain the focal position F at the center of the opening 61 of the mask 60 even immediately after the irradiation period is resumed, similarly to the first embodiment.

### 4.4 Modification

Next, a modification of the second embodiment will be described. In the present modification, similarly to the modification of the first embodiment, the opening 61 of the mask 60 is formed in a slit shape, and the converging lens 52 and the diverging lens 54 each are configured as a cylindrical lens further.

In the present modification, the converging lens 52 is a cylindrical lens that has optical power in the Y direction and focuses the laser beam Lb in the Y direction. The diverging lens 54 is a cylindrical lens that has optical power in the Y direction and has a function of adjusting the divergence angle in the Y direction of the laser beam Lb.

In the present modification, since the diverging lens 54 does not have optical power in the X direction, control of the diverging lens 54 in the X direction is unnecessary. As a result, an X-direction moving mechanism in the moving stage 55 can be omitted. Specifically, even if the diverging lens 54 is moved in the X direction, the focal position F of the laser beam Lb does not fluctuate in the X direction and the focusing accuracy relative to the opening 61 of the mask 60 is not affected. Therefore, there is no need to adjust the position of the diverging lens 54 in the X direction.

In the present modification, the laser processing processor 40 only needs to calculate the center coordinate yc in the Y direction and the width wy in the Y direction of the focal image based on the image D. The first control and the second control in the present modification are the same as those in the second embodiment, except that the diverging lens 54 is not moved in the X direction.

### 5. Third Embodiment

A laser processing system 1c according to the third embodiment of the present disclosure will be described. Configurations similar to those described above are denoted by identical reference signs, and duplicate description thereof is omitted unless otherwise specified.

### 5.1 Configuration

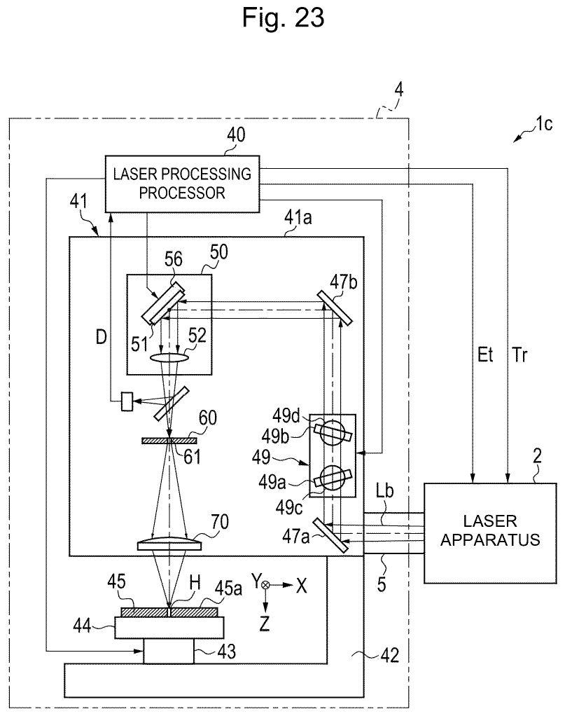

FIG. 23 schematically illustrates a configuration of the laser processing system 1c according to the third embodiment. The laser processing system 1c has the configuration the same as that of the laser processing system 1a according to the first embodiment, except for the illumination optical system 50.

In the present embodiment, the illumination optical system 50 includes the high reflective mirror 51, the converging lens 52, and a tilting stage 56 that holds the high reflective mirror 51. The high reflective mirror 51 has a role of adjusting the BP of the laser beam Lb and is configured to allow an angle to be changed in θx and θy directions by the tilting stage 56. Here, the θx direction is a rotation direction with an axis parallel to the Y direction as a rotation axis. The θy direction is a rotation direction with an axis parallel to the X direction as a rotation axis. In the present embodiment, the converging lens 52 is fixed and has optical power in the X and Y directions. Note that the high reflective mirror 51 is an example of a “mirror” according to technology of the present disclosure.

The tilting stage 56 is connected to the laser processing processor 40 and is controlled by the laser processing processor 40. In the present embodiment, the laser processing processor 40 adjusts the focal position F of the laser beam Lb by controlling the tilting stage 56 and adjusting an angle of the high reflective mirror 51 instead of moving the converging lens 52 as in the first embodiment. In the present embodiment, the focal position F can be adjusted in the X or Y direction.

### 5.2 Operation

The operation of the laser processing system 1c according to the third embodiment is the same as the operation of the laser processing system 1a according to the first embodiment, except for angle adjustment control of the high reflective mirror 51. Hereinafter, the angle adjustment control of the high reflective mirror 51 will be explained.

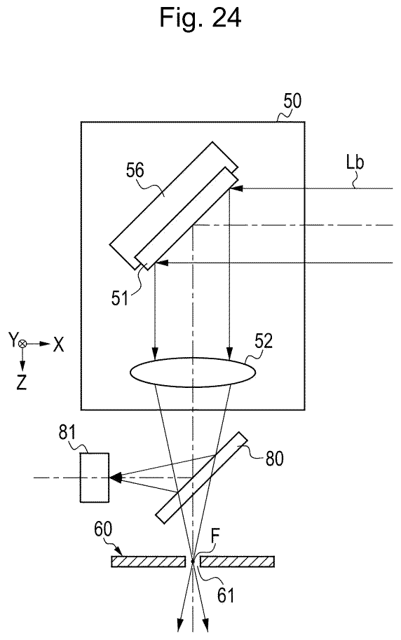

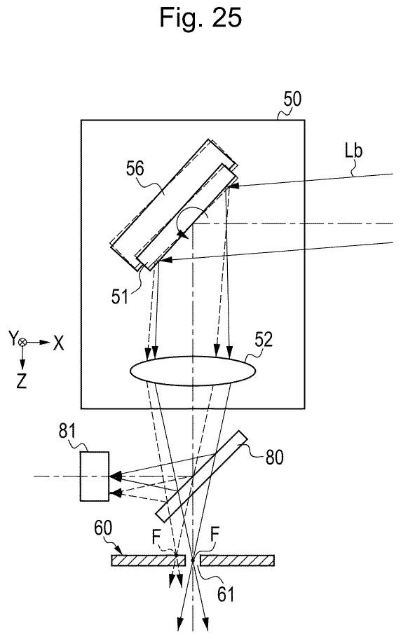

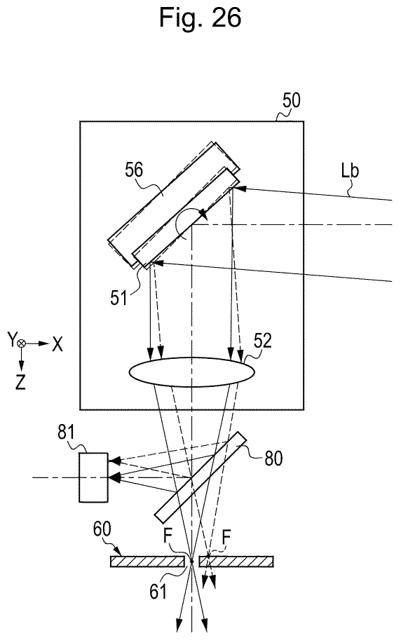

FIG. 24 illustrates the cold state or the low load state. FIG. 25 and FIG. 26 illustrate how the BP fluctuates in the high load state. As illustrated in FIG. 24, in the cold state or the low load state, the focal position F coincides with the center of the opening 61 of the mask 60.

As illustrated in FIG. 25, when the focal position F changes in the X direction due to the fluctuation of the BP, the laser processing processor 40 controls the tilting stage 56 to adjust the angle in the θx direction of the high reflective mirror 51. As a result, the focal position F is corrected to coincide with the center of the opening 61 of the mask 60.

As illustrated in FIG. 26, also when the focal position F changes in a direction opposite to that in FIG. 25 due to the fluctuation of the BP, the laser processing processor 40 controls the tilting stage 56 to adjust the angle in the θx direction of the high reflective mirror 51. As a result, the focal position F is corrected to coincide with the center of the opening 61 of the mask 60.

When the focal position F changes in the Y direction due to the fluctuation of the BP, the laser processing processor 40 controls the tilting stage 56 to adjust the angle in the θy direction of the high reflective mirror 51.

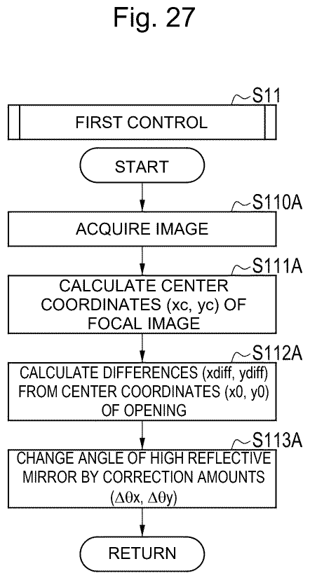

FIG. 27 illustrates a flow of the first control in the third embodiment. Steps S110A to S112A illustrated in FIG. 27 are the same as steps S110 to S112 described in the first embodiment. In the present embodiment, after step S112A, the laser processing processor 40 controls the tilting stage 56 and changes the angle of the high reflective mirror 51 by correction amounts (Δθx, Δθy) (step S113). The correction amounts (Δθx, Δθy) are expressed by following equations (7A) and (7B).

$$[ Expression 9 ]$$

$$Δ θ x = C 2 x \times xdiff \qquad ( 7 A )$$

$$[ Expression 10 ]$$

$$Δθy = C 2 y \times ydiff \qquad ( 7 B )$$

Here, C2x and C2y are proportional coefficients in the θx and θy directions, respectively, and represent a ratio of a change amount of the angle of the high reflective mirror 51 to the moving amount of the focal position F.

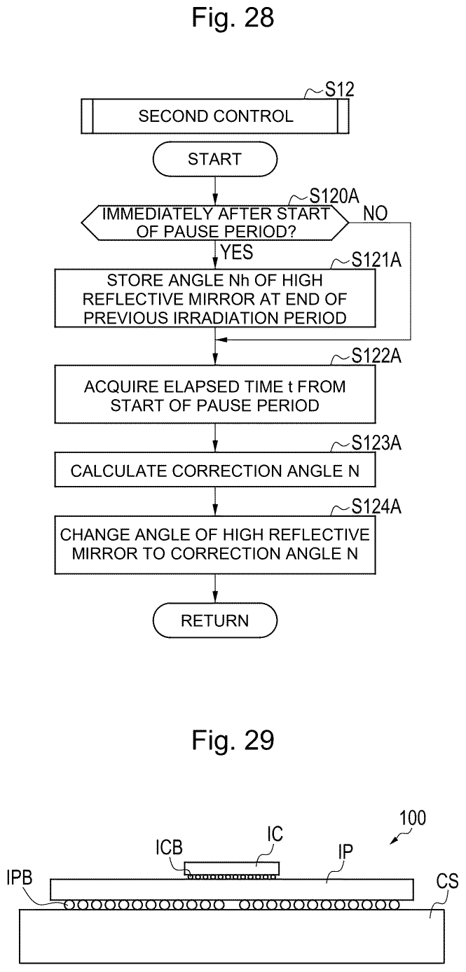

FIG. 28 illustrates a flow of the second control in the third embodiment. In the second control, the laser processing processor 40 first determines whether or not the current time point is immediately after the start of the pause period (step S120A). If it is determined that it is immediately after the start of the pause period (step S120A: YES), the laser processing processor 40 stores an angle Nh of the high reflective mirror 51 at the end of the previous irradiation period in a memory (step S121A). On the other hand, if it is not immediately after the start of the pause period (step S120A: NO), step S121A is not executed.

Thereafter, the laser processing processor 40 acquires the elapsed time t from the start of the pause period (step S122A) and calculates a correction angle N of the high reflective mirror 51 using a following equation (8) (step S123A). At the time, the laser processing processor 40 uses the angle Nh of the high reflective mirror 51 stored in step S121A and the elapsed time t acquired in step S122A. Then, the laser processing processor 40 controls the tilting stage 56 and changes the angle of the high reflective mirror 51 to the correction angle N (step S124A).

$$[ Expression 11 ]$$

$$N = Nh + ( Nc - Nh ) \times ( 1 - {\sum }_{i = 1}^{n} {C}_{i} {e}^{- t / {τ}_{i}} ) \qquad ( 8 )$$

Here, Nc is the angle of the high reflective mirror 51 in the cold state. Cᵢ is a contribution coefficient of the time constant tᵢ, and satisfies a relationship of the equation (6).

Note that the equation (8) does not distinguish the θx and θy directions. However, in each direction, the angle of the high reflective mirror 51 is corrected based on the attenuation curve represented by the equation (8).

### 5.3 Effect

According to the present embodiment, since the laser processing processor 40 corrects the angle of the high reflective mirror 51 based on the image D during the irradiation period, it is possible to effectively suppress the fluctuation of the focal position F relative to the opening 61 of the mask 60, similarly to the first embodiment. As a result, the stability of the focal position F is improved and it is possible to prevent a decrease in transmittance and to suppress damage to the mask 60.

Further, since the laser processing processor 40 adjusts the angle of the high reflective mirror 51 during the pause period, it is possible to highly accurately maintain the focal position F at the center of the opening 61 of the mask 60 even immediately after the irradiation period is resumed, similarly to the first embodiment.

### 5.4 Modification

Next, a modification of the third embodiment will be described. In the present modification, similarly to the modification of the first embodiment, the opening 61 of the mask 60 is formed in a slit shape and the converging lens 52 is formed as a cylindrical lens further.

In the present modification, the converging lens 52 is a cylindrical lens that has optical power in the Y direction and focuses the laser beam Lb in the Y direction.

In the present modification, since the converging lens 52 does not have optical power in the X direction, a θx-direction angle change mechanism in the tilting stage 56 can be omitted. As a result, control of the high reflective mirror 51 in the θx direction becomes unnecessary. Specifically, even if the angle of the high reflective mirror 51 is changed in the θx direction, the focal position F of the laser beam Lb does not fluctuate in the X direction and the focusing accuracy relative to the opening 61 of the mask 60 is not affected. Therefore, there is no need to adjust the angle of the high reflective mirror 51 in the ex direction.

In the present modification, since only the angle in the θy direction of the high reflective mirror 51 is adjusted, the laser processing processor 40 only needs to calculate the center coordinate yc in the Y direction of the focal image based on the image D. The first control and the second controls in the present modification are the same as those in the third embodiment, except that the angle of the high reflective mirror 51 is not changed in the θx direction.

Note that it is also possible to apply the angle adjustment of the high reflective mirror 51 in the third embodiment to the first or second embodiment and to execute it in combination with the position adjustment of the converging lens 52 or the diverging lens 54.

### 6. Electronic Device Manufacturing Method

A laser processing method according to the embodiments can be applied to formation of a through-hole in a substrate provided in an interposer IP in manufacturing of an electronic device 100 below.

FIG. 29 schematically illustrates a configuration of the electronic device 100. The electronic device 100 illustrated in FIG. 29 includes an integrated circuit chip IC, the interposer IP, and a circuit substrate CS. The integrated circuit chip IC is, for example, a chip in which a non-illustrated integrated circuit is formed on a silicon substrate. The integrated circuit chip IC is provided with a plurality of bumps ICB electrically connected to the integrated circuit.

The interposer IP includes an insulating substrate in which a plurality of non-illustrated through-holes are formed, and a non-illustrated conductor that electrically connects front and back surfaces of the substrate is provided in each of the through-holes. A plurality of non-illustrated lands connected to the bumps ICB are formed on one surface of the interposer IP, and each of the lands is electrically connected to any of the conductors in the through-holes. A plurality of bumps IPB are provided on the other surface of the interposer IP, and each of the bumps IPB is electrically connected to any of the conductors in the through-holes.

A plurality of non-illustrated lands connected to the bumps IPB are formed on one surface of the circuit substrate CS. The circuit substrate CS includes a plurality of terminals electrically connected to the lands.

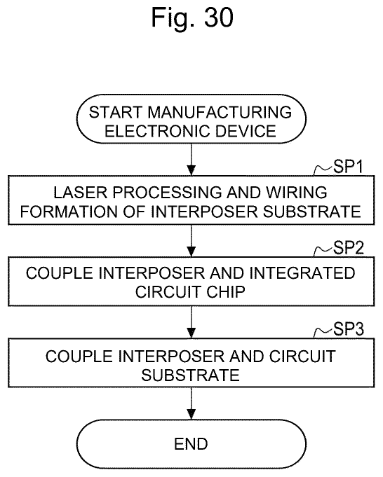

FIG. 30 illustrates a manufacturing method of the electronic device 100. First, in a first process SP1, laser processing and wiring formation of an interposer substrate forming the interposer IP are performed. The laser processing of the interposer substrate includes forming the through-holes by irradiating the interposer substrate with a pulse laser beam. The wiring formation includes forming a conductive film on an inner wall surface of the through-holes formed in the interposer substrate. By the first process SP1, the interposer IP is produced.

Next, in a second process SP2, the interposer IP and the integrated circuit chip IC are coupled. The second process SP2 includes, for example, disposing the bumps ICB of the integrated circuit chip IC on the lands of the interposer IP and electrically connecting the bumps ICB and the lands.

Then, in a third process SP3, the interposer IP and the circuit substrate CS are coupled. The third process SP3 includes, for example, disposing the bumps IPB of the interposer IP on the lands of the circuit substrate CS and electrically connecting the bumps IPB and the lands.

### 7. Configuration of Processor

The laser processing processor 40 and the laser processor 38 may be physically configured as hardware to execute various processes included in the present disclosure. For example, the laser processing processor 40 and the laser processor 38 may be a computer including a memory that stores a control program defining the various processes and a process device that executes the control program. The control program may be stored in one memory, or may be stored separately in a plurality of memories at physically separate locations, and the various processes may be defined by a combination of control programs stored in the memories. The process device may be a general-purpose process device such as a CPU (Central Processing Unit) or a special-purpose process device such as a GPU (Graphics Processing Unit).

Alternatively, the laser processing processor 40 and the laser processor 38 may be programmed as software to execute the various processes included in the present disclosure. For example, the laser processing processor 40 and the laser processor 38 may be implemented in a dedicated device such as an ASIC (Application Specific Integrated Circuit) or a programmable device such as a FPGA (Field Programmable Gate Array) so that functions of executing the various processes are provided thereto.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

The description above is intended to be illustrative and the present disclosure is not limited thereto. Therefore, it would be obvious to those skilled in the art that various modifications to the embodiments of the present disclosure would be possible without departing from the spirit and the scope of the claims. Further, it would be also obvious to those skilled in the art that the embodiments of the present disclosure would be appropriately combined. The terms used throughout the present specification and the claims should be interpreted as non-limiting terms unless clearly described. For example, terms such as “comprise”, “include”, “have”, and “contain” should not be interpreted to be exclusive of other structural elements. Further, indefinite articles “a/an” should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser processing apparatus that performs laser processing by irradiating a workpiece with a laser beam output from a laser apparatus, the laser processing apparatus comprising:
a mask disposed on an optical path of the laser beam and provided with an opening;
an illumination optical system configured to focus the laser beam to illuminate the opening;
a projection optical system configured to form an image of the opening on a surface of the workpiece;
a beam splitter disposed between the illumination optical system and the mask and configured to branch the laser beam;
an image sensor disposed on an optical path of the laser beam branched by the beam splitter and configured to generate an image including a focal image of the laser beam on the mask; and
a processor configured to correct a focal position of the laser beam relative to the opening by controlling the illumination optical system based on the generated image.

2. The laser processing apparatus according to claim 1, wherein
the processor changes the focal position in fixed cycles.

3. The laser processing apparatus according to claim 1, wherein
the illumination optical system includes a converging lens that focuses the laser beam and a moving stage that movably holds the converging lens, and
the processor corrects the focal position by controlling the moving stage based on the generated image and adjusting a position of the converging lens.

4. The laser processing apparatus according to claim 3, wherein
the opening has a slit shape, and
the converging lens is a cylindrical lens that has optical power in a width direction of the slit shape.

5. The laser processing apparatus according to claim 3, wherein
the processor adjusts the position of the converging lens based on a light amount peak position or a light amount centroid position of the focal image.

6. The laser processing apparatus according to claim 3, wherein
the processor adjusts the position of the converging lens based on a width of the focal image.

7. The laser processing apparatus according to claim 3, wherein
the processor calculates a correction position based on an attenuation curve representing change of the position of the converging lens and changes the position of the converging lens to the correction position during a pause period during which output of the laser beam from the laser apparatus is stopped.

8. The laser processing apparatus according to claim 7, wherein
the attenuation curve is expressed by an equation (1),
where P is the correction position, Pc is the position of the converging lens in a cold state, Ph is the position of the converging lens at an end of a previous irradiation period, t is elapsed time from a start of the pause period, τᵢ is a time constant, and Cᵢ is a contribution coefficient of the time constant τᵢ.
$$[ Expression 1 ]$$
$$P = Ph + ( Pc - Ph ) \times ( 1 - {\sum }_{i = 1}^{n} {C}_{i} {e}^{- t / {τ}_{i}} ) \qquad ( 1 )$$

9. The laser processing apparatus according to claim 1, wherein
the illumination optical system includes a converging lens that focuses the laser beam, a diverging lens disposed upstream of the converging lens, and a moving stage that movably holds the diverging lens, and
the processor corrects the focal position by controlling the moving stage based on the generated image and adjusting a position of the diverging lens.

10. The laser processing apparatus according to claim 9, wherein
the opening has a slit shape, and
the converging lens and the diverging lens each are a cylindrical lens that has optical power in a width direction of the slit shape.

11. The laser processing apparatus according to claim 9, wherein
the processor adjusts the position of the diverging lens based on a light amount peak position or a light amount centroid position of the focal image.

12. The laser processing apparatus according to claim 9, wherein
the processor adjusts the position of the diverging lens based on a width of the focal image.

13. The laser processing apparatus according to claim 9, wherein
the processor calculates a correction position based on an attenuation curve representing change of the position of the diverging lens and changes the position of the diverging lens to the correction position during a pause period during which output of the laser beam from the laser apparatus is stopped.

14. The laser processing apparatus according to claim 13, wherein
the attenuation curve is expressed by an equation (2),
where P is the correction position, Pc is the position of the diverging lens in a cold state, Ph is the position of the diverging lens at an end of a previous irradiation period, tis elapsed time from a start of the pause period, τᵢ is a time constant, and Cᵢ is a contribution coefficient of the time constant τᵢ.
$$[ Expression 2 ]$$
$$P = Ph + ( Pc - Ph ) \times ( 1 - {\sum }_{i = 1}^{n} {C}_{i} {e}^{- t / {τ}_{i}} ) \qquad ( 2 )$$

15. The laser processing apparatus according to claim 1, wherein
the illumination optical system includes a mirror that reflects the laser beam, a converging lens that focuses the laser beam, and a tilting stage that holds the mirror at an adjustable angle, and
the processor corrects the focal position by controlling the tilting stage based on the generated image and adjusting the angle of the mirror.

16. The laser processing apparatus according to claim 15, wherein
the opening has a slit shape, and
the converging lens is a cylindrical lens that has optical power in a width direction of the slit shape.

17. The laser processing apparatus according to claim 15, wherein
the processor adjusts the angle of the mirror based on a light amount peak position or a light amount centroid position of the focal image.

18. The laser processing apparatus according to claim 15, wherein
the processor calculates a correction angle based on an attenuation curve representing change of the angle of the mirror and changes the angle of the mirror to the correction angle during a pause period during which output of the laser beam from the laser apparatus is stopped.

19. The laser processing apparatus according to claim 18, wherein
the attenuation curve is expressed by an equation (3),
where N is the correction angle, Nc is the angle of the mirror in a the cold state, Nh is the angle of the mirror at an end of a previous irradiation period, tis elapsed time from a start of the pause period, τᵢ is a time constant, and Cᵢ is a contribution coefficient of the time constant τᵢ.
$$[ Expression 3 ]$$
$$N = Nh + ( Nc - Nh ) \times ( 1 - {\sum }_{i = 1}^{n} {C}_{i} {e}^{- t / {τ}_{i}} ) \qquad ( 3 )$$

20. An electronic device manufacturing method comprising:
producing an interposer by laser processing an interposer substrate with a laser processing apparatus, the laser processing apparatus performing laser processing by irradiating a workpiece with a laser beam output from a laser apparatus and including
a mask disposed on an optical path of the laser beam and provided with an opening,
an illumination optical system configured to focus the laser beam to illuminate the opening,
a projection optical system configured to form an image of the opening on a surface of the workpiece,
a beam splitter disposed between the illumination optical system and the mask and configured to branch the laser beam,
an image sensor disposed on an optical path of the laser beam branched by the beam splitter and configured to generate an image including a focal image of the laser beam on the mask, and
a processor configured to correct a focal position of the laser beam relative to the opening by controlling the illumination optical system based on the generated image;
coupling and electrically connecting the interposer and an integrated circuit chip to each other; and
coupling and electrically connecting the interposer and a circuit substrate to each other.
